(19) United States
(12) Patent Application Publication
(10) Pub. No.: US 2011/0203611 A1
(43) Pub. Date: Aug. 25, 2011

(54) MASK CLEANING METHOD, MASK CLEANING APPARATUS, AND PELLICLE

(76) Inventors: Eri UEMURA, Yokohama-Shi (JP); Makiko KATANO, Yokohama-Shi (JP); Yuji YAMADA, Yokohama-Shi (JP)

(21) Appl. No.: 12/965,006

(22) Filed: Dec. 10, 2010

(30) Foreign Application Priority Data
Feb. 23, 2010 (JP) 2010-37144

(51) Int. Cl. B08B 5/00; G03F 1/00; B08B 7/00

(52) U.S. Cl. 134/3; 430/5; 156/345.1; 156/345.29; 134/19; 134/31; 134/30

(57) ABSTRACT

Embodiments disclose a method for cleaning a mask having a mask film that is of a surface to which a foreign substance containing silicon oxide adheres. In the method, the mask is retained in a cleaning gas containing diluted hydrofluoric acid vapor at a temperature at which an etching rate to the foreign substance becomes higher than an etching rate to the mask film. Further, in the method, the cleaning gas is supplied to the surface of the mask to etch the foreign substance.

### CROSS REFERENCE TO RELATED APPLICATION

This application is based upon and claims benefit of priority from the Japanese Patent Application No. 2010-037144, filed on Feb. 23, 2010, the entire contents of which are incorporated herein by reference.

### FIELD

Embodiments described herein relate generally to a mask cleaning method, a mask cleaning apparatus, and a pellicle.

### BACKGROUND

Conventionally, there is a well known halftone type phase shift mask producing method in which cleaning is performed by an alkaline treatment, an acid treatment, or the both treatments after a semi-translucent film pattern containing MoSi is formed with a light-shielding pattern as a mask (for example, see JP-A 2003-121978 (KOKAI)).

However, the acid treatment is performed with the light-shielding pattern as the mask while the semi-translucent film pattern is not exposed, and the acid treatment cannot be performed while the semi-translucent film pattern containing MoSi is exposed to a surface.

### BRIEF DESCRIPTION OF THE DRAWINGS

FIG. 1 is a schematic diagram of a mask cleaning apparatus according to a first embodiment of the invention;

FIG. 2 is a graph illustrating temperature dependence of etching rates of a SiO₂ film and a SiN film by DHF vapor;

FIG. 3 is a schematic diagram of a mask cleaning method according to a second embodiment of the invention; and

FIG. 4 is a schematic diagram of a mask cleaning apparatus according to a third embodiment of the invention.

### DETAILED DESCRIPTION

Embodiments disclose a method for cleaning a mask having a mask film that is of a surface to which a foreign substance containing silicon oxide adheres. In the method, the mask is retained in a cleaning gas containing diluted hydrofluoric acid vapor at a temperature at which an etching rate to the foreign substance becomes higher than an etching rate to the mask film. Further, in the method, the cleaning gas is supplied to the surface of the mask to etch the foreign substance.

### First Embodiment

### Configuration of Mask Cleaning Apparatus

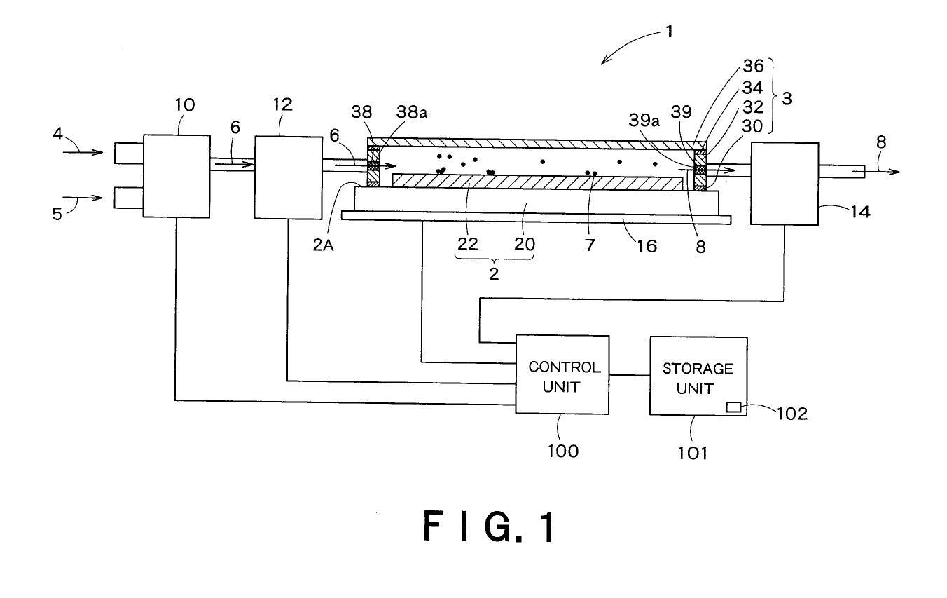

FIG. 1 is a schematic diagram of a mask cleaning apparatus according to a first embodiment of the invention. For example, a mask cleaning apparatus 1 cleans a mask 2 used in an exposure treatment in producing a semiconductor device.

The mask cleaning apparatus 1 mainly includes a heating unit 16 and a Diluted Hydrofluoric Acid (DHF) vapor adjusting unit 10. The heating unit 16 that is of the retention unit retains the mask 2 in the cleaning gas containing DHF vapor at the temperature at which the etching rate to a haze 7 becomes higher than the etching rate to a mask film 22. The mask film 22 is provided on a surface 2A of the mask 2, and the haze 7 that is of the foreign substance containing the silicon oxide adheres to the mask film 22. The DHF vapor adjusting unit 10 that is of the supply unit supplies the cleaning gas to the surface of the mask 2 to etch the haze 7.

As illustrated in FIG. 1, the mask cleaning apparatus 1 also includes first and second flow rate adjusting units 12 and 14, a control unit 100, and a storage unit 101.

The DHF vapor adjusting unit 10 adjusts supplied DHF vapor 4 and inert gas to generate a mixed gas 6. For example, a water amount in the DHF vapor 4 satisfies DHF:H₂O=4:6. The inert gas, for example, is an N₂ gas 5. In the mixed gas 6 that is of the cleaning gas, for example, the DHF vapor 4 and the N₂ gas 5 are mixed at a predetermined ratio. For example, the mixture ratio (predetermined ratio) of the DHF vapor 4 and the N₂ gas 5 is determined from an etching time or a ratio at which the etching rates of the mask film 22 and the haze 7 become optimum.

The DHF vapor adjusting unit 10 adjusts a temperature of the DHF vapor 4. The temperature of the DHF vapor 4 is adjusted within a temperature range of the retained mask 2 in order to efficiently remove the haze 7.

A first flow rate adjusting unit 12 adjusts a flow rate of a mixed gas 6 supplied into a pellicle 3 through an intake opening 38 that is of the first opening. A second flow rate adjusting unit 14 adjusts a flow rate of an exhaust gas 8 exhausted from an exhaust opening 39 that is of the second opening.

A heating unit 16 includes a heating wire therein, and the heating unit 16 passes a current through the heating wire to heat the mask 2. In the first embodiment, it is assumed that room temperature is set to 20° C. The heating unit 16 has a configuration in which the mask 2 is cooled when a temperature range where a difference in etching rate generated between the mask film 22 and the haze 7 is lower than the mask 2 at the room temperature.

For example, a control unit 100 is a microcomputer including a Central Processing Unit (CPU). The control unit 100 controls the DHF vapor adjusting unit 10, the first and second flow rate adjusting units 12 and 14, and the heating unit 16 based on a program 102 stored in a storage unit 101.

The control unit 100 controls the DHF vapor adjusting unit 10 such that the water amount and temperature in the DHF vapor 4 and the ratio of the DHF vapor 4 and the N₂ gas 5 become set values.

The control unit 100 controls the first flow rate adjusting unit 12 such that the mixed gas 6 becomes a predetermined flow rate. The control unit 100 controls the second flow rate adjusting unit 14 such that an exhaust gas 8 becomes a predetermined flow rate. For example, the flow rates of the mixed gas 6 and the exhaust gas 8 are adjusted so as to become equal to each other, and preferably the flow rates ranges from 0.1 to 0.5 L/min. The flow rates of the mixed gas 6 and the exhaust gas 8 may differ from each other to an extent in which a pellicle film 36 is not damaged.

The control unit 100 controls the heating performed by the heating unit 16 such that the pellicle 3 becomes 80° C. or less.

The storage unit 101 is a storage device including, for example, a Hard Disk Drive (HDD) or a semiconductor memory to store the program 102.

The program 102 stores, for example, a process of the method for cleaning the mask 2 and commands to control the DHF vapor adjusting unit 10, the first and second flow rate adjusting units 12 and 14, and the heating unit 16. The control unit 100 executes the program 102.

The mask 2 is, for example, a halftone mask that is of a multiple-tone mask, and a mask film 22 is formed on the side of the surface 2A of a substrate 20 as illustrated in FIG. 1. The mask film 22 is covered with the pellicle 3. The mask 2 is not limited to the halftone mask. A gray tone mask that is of the multiple-tone mask, a binary mask that is of a two-tone mask whose mask pattern is made of Cr or the like, or a reflection type mask that is used in an Extreme Ultra Violet (EUV) lithographic method may be used as the mask 2.

The substrate 20 is, for example, a Si substrate mainly containing Si.

The mask film 22 is, for example, a film mainly containing MoSi or SiN. A mask pattern is formed in the mask film 22.

The pellicle 3 prevents dust and the like from adhering to the mask film 22, and a surface of the pellicle 3 is made of a material having hydrofluoric-acid resistance. The surface is, for example, an inner surface of the pellicle 3 with which the mixed gas 6 probably comes into contact. The pellicle 3 includes a pellicle frame 32 and a pellicle film 36. The pellicle frame 32 is provided on the substrate 20 with an adhesive agent 30 interposed therebetween, and the pellicle film 36 is provided on the pellicle frame 32 with a bonding agent 34 interposed therebetween.

For example, silicone and fluorine resin, which has the high hydrofluoric-acid resistance and generates little gas, is used as the adhesive agent 30.

The pellicle frame 32 is, for example, made of a material, such as a carbon resin and a fluorine resin, which has the hydrofluoric-acid resistance. In the pellicle frame 32, the surface of the frame made of aluminum may be coated with a material (such as a fluorine resin) having the hydrofluoric-acid resistance.

The pellicle frame 32 includes at least one intake opening 38 and at least one exhaust opening 39, the exhaust opening 39 is formed in the pellicle frame 32 that is in the opposite to the intake opening 38. Filters 38a and 39a are provided in the intake opening 38 and the exhaust opening 39 in order to prevent, for example, the dust and the like. Desirably at least two intake openings 38 and at least two exhaust openings 39 are formed in the pellicle frame 32.

The intake opening 38 is connected, for example, to the first flow rate adjusting unit 12. The exhaust opening 39 is connected, for example, to the second flow rate adjusting unit 14. Conventionally, because the flow rates of the mixed gas 6 and the exhaust gas 8 are equal to each other, the intake opening 38 and the exhaust opening 39 can be formed while exceeding sizes at which the pellicle film 36 is possibly damaged.

The filters 38a and 39a are made of a material, for example, Polytetrafluoroethylene (PTFE) having the hydrofluoric-acid resistance, in which having the hydrofluoric-acid resistance while the dust is not generated in supplying and exhausting the gas.

Desirably the pellicle film 36 is made of a material having no absorbance of the exposure light, high transmittance (99% or more) of the exposure light, and the hydrofluoric-acid resistance. For example, the pellicle film 36 is made of a fluorine organic compound.

For example, a fluorine resin having the hydrofluoric-acid resistance and high adhesive strength is used as the bonding agent 34.

(Mask Cleaning Method)

An example of the method for cleaning the mask 2 in which the haze 7 is grown on the mask film 22 due to the repetitive use in the exposure treatment will be described below. As used herein, the haze 7 means a growth foreign substance that is generated in the exposure treatment, and the foreign substance that is grown by the adhesion of a trace substance adhering onto the mask film 22 from environmental atmosphere of the exposure treatment. The cleaning method in the case where the foreign substance containing the silicon oxide adheres to the mask film 22 as the haze 7 will be described.

First the mask 2 is prepared. The mask film 22 to which the haze 7 adheres is provided on the surface 2A of the mask 2. The pellicle 3 adheres onto the mask 2. Then, the mask 2 is placed on the heating unit 16 of the mask cleaning apparatus 1, the first flow rate adjusting unit 12 is connected to the intake opening 38 of the pellicle 3, and the second flow rate adjusting unit 14 is connected to the exhaust opening 39.

Then the control unit 100 of the mask cleaning apparatus 1 controls the DHF vapor adjusting unit 10 such that the mixed gas 6 is generated from the DHF vapor 4 and the N₂ gas 5. The mixed gas 6 is supplied into the pellicle 3 while containing the DHF vapor 4 that becomes the water amount and the temperature as described above, for example.

Then, the control unit 100 controls the first flow rate adjusting unit 12 such that the flow rate of the mixed gas 6 becomes a predetermined flow rate, and the control unit 100 controls the second flow rate adjusting unit 14 such that the flow rate of the exhaust gas 8 that is of the first exhaust gas is equal to the flow rate of the mixed gas 6. The control unit 100 controls the heating unit 16 while supplying the mixed gas 6, and the control unit 100 heats the substrate 20 in an optimum temperature range. The optimum temperature range will be described below.

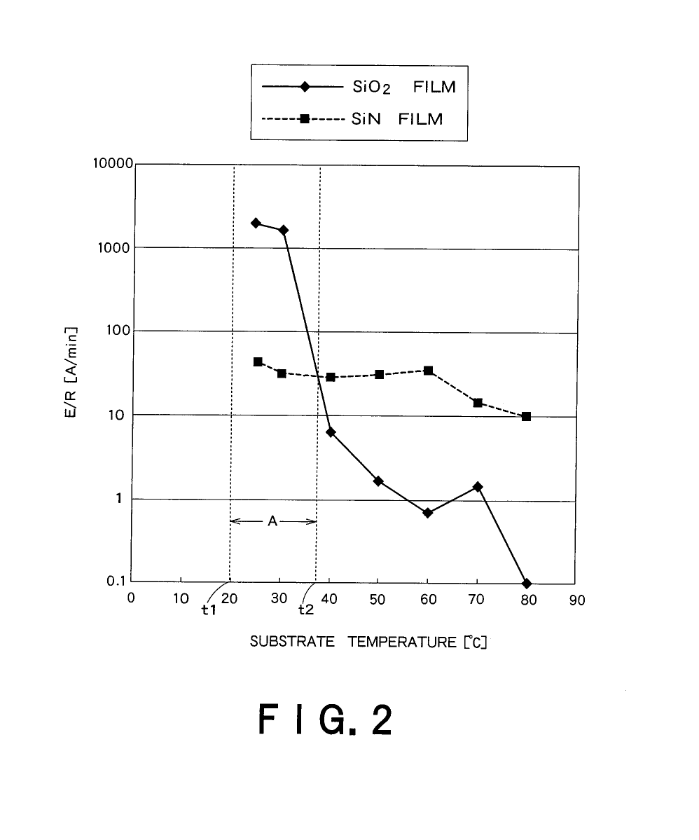

FIG. 2 is a graph illustrating temperature dependence of etching rates of the SiO₂ film and the SiN film by the DHF vapor. In FIG. 2, a horizontal axis indicates a temperature (° C.) at the substrate 20, and a vertical axis indicates an etching rate (Å/min). A temperature t1 (for example, about 20° C.) illustrated in FIG. 2 is a boiling temperature of the hydrofluoric acid in order to generate the DHF vapor 4.

As illustrated in FIG. 2, when the etching rates of the SiO₂ film and the SiN film are compared to each other, the etching rates of the SiO₂ film and the SiN film become substantially equal to each other at a temperature t2 (for example, about 38° C.) at the substrate 20. The haze 7 contains SiO₂ and the mask film 22 contains SiN. Therefore, as illustrated in FIG. 2, the temperature range where the etching rate to the haze 7 that is of the cleaning object is higher than the etching rate to the mask film 22 formed on the mask 2 becomes a temperature range A of t1 to t2 in the mixed gas 6 containing the DHF vapor 4.

Because the change in etching rate of the SiO₂ film at 30° C. or less is smaller than the change in etching rate of the SiO₂ film in other temperature ranges, the optimum temperature at which the cleaning treatment is performed ranges, for example, from 20° C. to 30° C.

In the etching treatment of the haze 7 with the mixed gas 6 containing the DHF vapor 4, because the etching rate at a low temperature (for example, a temperature lower than 38° C.) is in the order of SiO₂>MoSi (SiN)>Cr, only the foreign substance containing the silicon oxide is etched even if MoSi is exposed to the mask film 22.

After the etching treatment is ended, the control unit 100 replaces the atmosphere in the pellicle 3 with, for example, Clean Dry Air (CDA) or the N₂ gas while heating the substrate 20, and the cleaning treatment is ended. The heating unit 16 heats the substrate 20 at a temperature of 80° C. or less based on heatproof temperatures of the adhesive agent 30 and the bonding agent 34.

### Effect of First Embodiment

According to the mask cleaning method of the first embodiment, the haze 7 containing the silicon oxide that is hardly removed in the conventional technique is removed while the pattern shape formed in the mask film 22 is maintained, so that the mask 2 can be reused. According to the mask cleaning method, the haze 7 adhering to the mask film 22 is removed, so that a yield of the semiconductor device that is produced with the mask 2 after the cleaning can be enhanced. Further, according to the mask cleaning method, the yield is enhanced and the mask 2 is reused, so that production cost of the semiconductor device can be held down.

According to the mask cleaning method, the cleaning treatment of the mask 2 can be performed while the pellicle 3 adheres to the mask 2. According to the mask cleaning method, because the flow rates of the mixed gas 6 and the exhaust gas 8 are equalized to each other, the intake opening 38 and the exhaust opening 39 can be formed larger compared with the case where the flow rates are not equalized. According to the mask cleaning method, because the supply of the mixed gas 6 can be increased, the mask 2 can efficiently be cleaned, and a time necessary to produce the semiconductor device can be shortened.

According to the mask cleaning method, the gas generated from the bonding agent 34 and the like can be removed by the heating treatment after the etching treatment with the mixed gas 6 containing the DHF vapor 4.

In the pellicle 3, because the intake opening 38 and the exhaust opening 39 can widely be formed to increase the supply of the mixed gas 6, the mask 2 can efficiently be cleaned, and the time necessary to produce the semiconductor device can be shortened.

### Second Embodiment

A second embodiment differs from the first embodiment in that the mask to which the pellicle does not adhere is cleaned. Hereinafter, a component having the function and configuration similar to those of the first embodiment is designated by the similar numeral, and the description is omitted.

(Mask Cleaning Method)

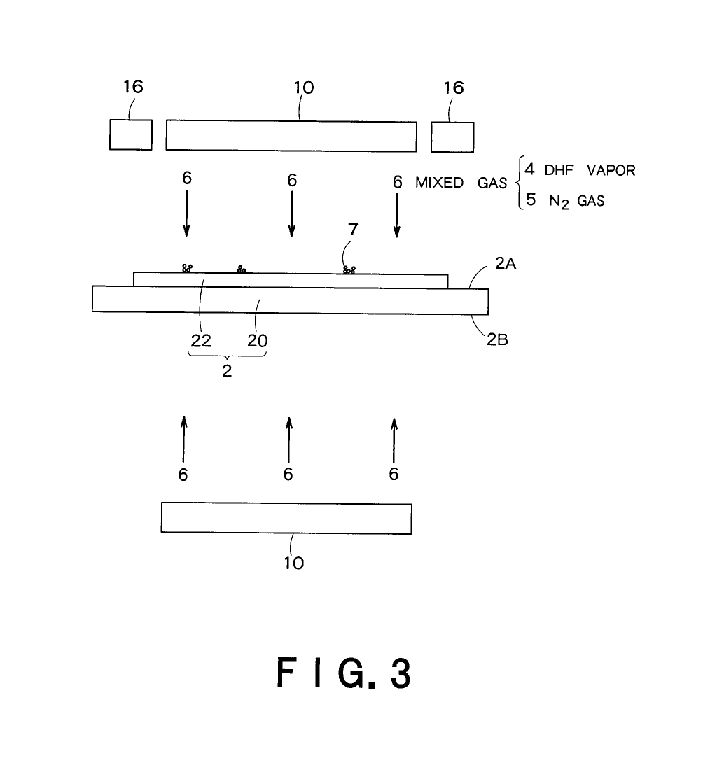

FIG. 3 is a schematic diagram of a mask cleaning method according to a second embodiment of the invention. The pellicle 3 adhering to the mask 2 is peeled off. The haze 7 is grown on the mask film 22 formed on the mask 2 that is repeatedly used in the exposure treatment.

Then, as illustrated in FIG. 3, the mixed gas 6 generated by the DHF vapor adjusting unit 10 is blown from the side of the surface 2A on which the mask film 22 of the mask 2 are formed and a side of a rear surface 2B, the heating unit 16 heats the mask 2 in the optimum temperature range to perform the etching treatment of the haze 7. The mixed gas 6 contains the DHF vapor 4 that becomes the water amount and the temperature range as described above, for example.

After the etching treatment is ended, the CDA or the N₂ gas is blown on surface 2A and the rear surface 2B of the substrate 20 to remove the remaining DHF vapor 4, and the cleaning treatment is ended.

The treatment of removing the remaining DHF vapor 4 is performed, for example, while the substrate 20 is heated. Because the heating treatment is performed to the mask 2 in which the pellicle 3 is peeled off, the heating treatment may be performed at a temperature higher than that of the first embodiment.

After the cleaning treatment, the cleaning treatment may be performed in order to remove the haze 7 except the silicon oxide. The mixed gas 6 may be blown on only either one of the surface 2A and the rear surface 2B of the mask 2. The CDA or the N₂ gas may be blown on only either one of the surface 2A and the rear surface 2B of the mask 2.

### Effect of Second Embodiment

According to the mask cleaning method of the second embodiment, the haze 7 containing the silicon oxide that is hardly removed in the conventional technique is removed while the pattern shape formed in the mask film 22 is maintained, so that the mask 2 can be reused.

According to the mask cleaning method, the cleaning treatment is performed in order to remove the haze 7 except the silicon oxide after the haze 7 containing the silicon oxide is removed, so that the mask 2 to which the foreign substance does not adhere can be obtained. Further, according to the mask cleaning method, the haze 7 adhering to the mask film 22 is removed, so that the yield of the semiconductor device that is produced with the mask 2 after the cleaning can be enhanced. According to the mask cleaning method, the yield is enhanced and the mask 2 is reused, so that the production cost of the semiconductor device can be held down.

### Third Embodiment

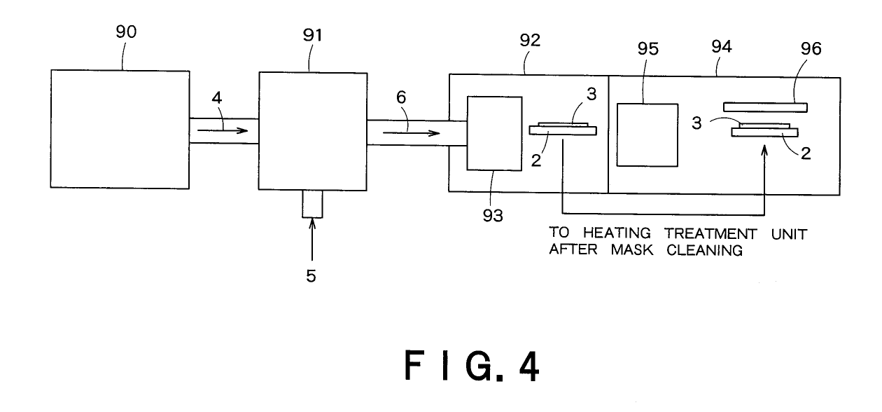

FIG. 4 is a schematic diagram of a mask cleaning apparatus according to a second embodiment of the invention. As illustrated in FIG. 4, a mask cleaning apparatus 9 includes a DHF vapor generating unit 90, a DHF vapor adjusting unit 91, a mask cleaning unit 92, and a heating treatment unit 94.

The DHF vapor generating unit 90 generates the DHF vapor 4 for example.

The DHF vapor adjusting unit 91 adjusts, for example, the water amount and the temperature of the DHF vapor 4 generated in the DHF vapor generating unit 90, and the DHF vapor adjusting unit 91 delivers the adjusted DHF vapor 4 and the mixed gas 6 containing the N₂ gas 5 to the mask cleaning unit 92.

The mask cleaning unit 92 includes a purge mechanism 93. The purge mechanism 93 has a function similar to those of the first and second flow rate adjusting units 12 and 14 of the first embodiment, and the purge mechanism 93 performs the adjustment such that the flow rate of the mixed gas 6 supplied to the pellicle 3 is equal to the flow rate of the exhausted exhaust gas.

The heating treatment unit 94 includes a purge mechanism 95 and a heating mechanism 96. The purge mechanism 95 has a function similar to those of the first and second flow rate adjusting units 12 and 14 of the first embodiment, and the purge mechanism 95 performs the adjustment such that the flow rate of the CDA or the N₂ gas supplied to the pellicle 3 is equal to the flow rate of the exhausted exhaust gas.

The heating mechanism 96 has a function, for example, similar to that of the heating unit 16 of the first embodiment, and the heating mechanism 96 heats the mask 2.

The mask cleaning apparatus 9 includes, for example, the control unit 100 and the storage unit 101 of the first embodiment. The control unit 100 controls, for example, the DHF vapor generating unit 90, the DHF vapor adjusting unit 91, the mask cleaning unit 92, and the heating treatment unit 94.

(Mask Cleaning Method)

First the mask 2 with the pellicle 3 is put in the mask cleaning unit 92 of the mask cleaning apparatus 9.

Then the DHF vapor generating unit 90 generates the DHF vapor 4 to deliver the DHF vapor 4 to the DHF vapor adjusting unit 91.

After the DHF vapor adjusting unit 91 adjusts the temperature and the water amount of the DHF vapor 4, and the DHF vapor 4 is delivered to the mask cleaning unit 92 in the form of the mixed gas 6 containing the N₂ gas 5. The temperature of the mixed gas 6 is set to an optimum temperature at which the difference in etching rate is generated, and the treatment is performed such that the temperature at the mask 2 becomes the optimum temperature by the mixed gas 6.

The purge mechanism 93 of the mask cleaning unit 92 supplies the mixed gas 6 into the pellicle 3.

Then, the purge mechanism 93 performs the adjustment such that the flow rate of the mixed gas 6 becomes a predetermined flow rate, and the purge mechanism 93 performs the adjustment such that the flow rate of the exhaust gas 8 is equal to the flow rate of the mixed gas 6.

After the etching treatment is ended, the mask 2 is conveyed from the mask cleaning unit 92 to the heating treatment unit 94. In the heating treatment unit 94, for example, while the heating mechanism 96 heats the substrate 20, the atmosphere in the pellicle 3 is replaced with the CDA or N₂ gas that is delivered from the purge mechanism 95. The purge mechanism 95 of the heating treatment unit 94 performs, for example, the adjustment such that the flow rate of the gas supplied to the intake opening 38 is equal to the flow rate of the gas exhausted from the exhaust opening 39. The temperature in the heating treatment that is performed to the substrate 20 by the heating mechanism 96 is, for example, set identical to the temperature of the first embodiment.

The mask cleaning apparatus 9 ends the cleaning treatment after performing the above described treatment. In the cleaning method of the third embodiment, the pellicle 3 adheres to the mask 2. The cleaning treatment may be performed to the mask 2 from which the pellicle 3 is peeled off or the mask 2 to which the pellicle 3 does not adhere.

### Effect of Third Embodiment

In the mask cleaning apparatus 9 of the third embodiment, the haze 7 containing the silicon oxide adhering to the mask film 22 can be removed while the pattern shape of the mask film 22 formed in the mask 2 is maintained. According to the mask cleaning apparatus 9, the cleaning treatment of the mask 2 can be performed while the pellicle 3 adheres to the mask 2. According to the mask cleaning apparatus 9, because the flow rates of the mixed gas 6 and the exhaust gas 8 are equalized to each other, the intake opening 38 and the exhaust opening 39 can be formed larger compared with the case where the flow rates are not equalized. According to the mask cleaning apparatus 9, because the supply of the mixed gas 6 can be increased, the mask 2 can efficiently be cleaned, and the time necessary to produce the semiconductor device can be shortened.

According to the mask cleaning apparatus 9, in the mask to which the pellicle 3 does not adhere, the cleaning treatment is performed in order to remove the haze 7 except the silicon oxide after the haze 7 containing the silicon oxide is removed, so that the mask 2 to which the foreign substance does not adhere can be obtained.

According to the mask cleaning apparatus 9, the haze 7 adhering to the mask film 22 is removed, so that the yield of the semiconductor device that is produced with the mask 2 after the cleaning can be enhanced. According to the mask cleaning apparatus 9, the yield is enhanced and the mask 2 is reused, so that the production cost of the semiconductor device can be held down.

In the embodiments, the DHF vapor 4 and the N₂ gas 5 are supplied into the pellicle 3 in the form of the mixed gas 6. Alternatively, the DHF vapor 4 and the N₂ gas 5 may separately be supplied into the pellicle 3.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A mask cleaning method comprising:
preparing a mask in which a mask film is formed on a surface thereof, a foreign substance containing silicon oxide adhering to the mask film;
retaining the mask at a temperature at which an etching rate to the foreign substance is higher than an etching rate to the mask film in a cleaning gas containing diluted hydrofluoric acid vapor; and
etching the foreign substance by supplying the cleaning gas to the surface of the mask.

2. The mask cleaning method according to claim 1, further comprising placing a pellicle on the mask before the cleaning gas is supplied, a surface of the pellicle being made of a material having hydrofluoric-acid resistance,
wherein the cleaning gas is supplied into the pellicle.

3. The mask cleaning method according to claim 2, wherein etching the foreign substance is performed such that a flow rate of the cleaning gas that is supplied into the pellicle from a first opening formed in the pellicle placed on the mask is equal to a flow rate of exhaust gas exhausted from a second opening formed in the pellicle.

4. The mask cleaning method according to claim 3, wherein an atmosphere in the pellicle is replaced with Clean Dry Air (CDA) or N₂ gas while the mask is heated, after the foreign substance is etched.

5. The mask cleaning method according to claim 1, wherein the foreign substance is etched while a temperature at the mask is maintained in a range of 20° C. to 30° C.

6. The mask cleaning method according to claim 1, wherein the mask film contains MoSi or SiN.

7. A pellicle that is used in the mask cleaning method according to claim 2, the surface of the pellicle being made of the material having the hydrofluoric-acid resistance.

8. The pellicle according to claim 7, wherein the material having the hydrofluoric-acid resistance has transmittance of 99% or more to exposure light.

9. The pellicle according to claim 7, comprising:
a pellicle frame that is provided on a substrate, on which the mask film is provided, while an adhesive agent is interposed between the pellicle frame and the substrate; and
a pellicle film that is provided on the pellicle frame with a bonding agent interposed therebetween,
wherein the pellicle film is made of a material having the hydrofluoric-acid resistance.

10. The pellicle according to claim 9, wherein at least one intake opening and at least one exhaust opening are formed in the pellicle frame, the exhaust opening being opposite to the intake opening.

11. The pellicle according to claim 10, wherein at least two intake openings and at least two exhaust openings are formed.

12. The pellicle according to claim 10, further comprising filters that are provided in the intake opening and the exhaust opening respectively, the filters being made of a material having the hydrofluoric-acid resistance.

13. A mask cleaning apparatus comprising:
a retention unit that retains a mask at a temperature at which an etching rate to a foreign substance containing silicon oxide is higher than an etching rate to a mask film in a cleaning gas containing diluted hydrofluoric acid vapor, the mask film being formed on a surface of the mask; and
a supply unit that supplies the cleaning gas to the surface of the mask to etch the foreign substance.

14. The mask cleaning apparatus according to claim 13, further comprising:
a first adjusting unit that adjusts a flow rate of the cleaning gas that is supplied into the pellicle from a first opening formed in the pellicle placed on the mask; and
a second adjusting unit that adjusts a flow rate of exhaust gas exhausted from a second opening formed in the pellicle.
